(19) United States
(12) Patent Application Publication
(10) Pub. No.: US 2005/0035806 A1
(43) Pub. Date: Feb. 17, 2005

(54) Circuit and method to protect EEPROM data during ESD events

(76) Inventors: Alaa Y. El-Sherif, Plano, TX (US); Robert W. Mounger, Dallas, TX (US)

Correspondence Address: Dan Swayze;Texas Instruments Incorporated, M/S 3999, P.O.Box 655474, Dallas, TX, 75265, US

(21) Appl. No.: 10/626,091

(22) Filed: Jul. 24, 2003

(51) Int. Cl. H03L 5/00

(52) U.S. Cl. 327/306

(57) ABSTRACT

The present invention comprises a clamp circuit (104) comprised of a first transistor (111), a second transistor (112), a voltage divider circuit and a delay circuit (105) comprised of a fourth transistor (114), a fifth transistor (115), a sixth transistor (116) and a seventh transistor (117) and a fifth resistor (125), operable to keep the signals at the EEPROM input nodes (131) and (132) of a data cell, such as an EEPROM cell below a certain voltage threshold, preferable below 10 volts.

### FIELD OF THE INVENTION

The present invention generally relates to circuits and method for minimizing the effects of electrostatic discharge (“ESD”) events when using electrically erasable programmable read only memory (“EEPROM”) cells to fine tune and reduce the effects of manufacturing variations in circuits, such as servo integrated circuits (“ICs”).

### BACKGROUND OF THE INVENTION

A small number of electrically erasable programmable read only memory (“EEPROM”) cells (typically less than one hundred bits) is used on servo controller integrated circuits (“ICs”) as a cost effective means of fine tuning performance of the silicon and reducing the effect of manufacturing variations. The bits are programmed by inducing a fifteen (15) to twenty (20) volt level on internal circuit nodes, which can be selected to program or erase a particular bit.

Occasionally, a high voltage is inadvertently introduced on servo controller IC's as electrostatic discharge (“ESD”) induced by ordinary handling of the IC's or during ESD quality tests. This ESD can result in the reprogramming or erasure of a bit or several bits of the EEPROM.

### SUMMARY OF THE INVENTION

The present invention achieves technical advantages as a circuit and method for greatly reducing or eliminating the risk of ESD induced reprogramming or erasure while retaining the ability to program the device in package. ESD is a nearly instantaneous event. The present invention overcomes the difficulty posed by this fact with a combination of circuits that delay the propagation of the high voltage spike and then clamp internal nodes under ESD conditions.

Other ESD protection methods require the EEPROM bits to be trimmed for optimum performance at the wafer level with a multi-probe test via an additional internal probe pad. Disadvantageously, some parameters can shift in the process of dicing each IC from the wafer, mounting it on a lead frame and encapsulating it in a plastic package. Thus, a circuit and method of EEPROM programming after packaging the device is desired. Accordingly, performance loss can be eliminated if the device is programmed after packaging and better yield levels can be achieved during the final test of packaged parts. The present invention advantageously retains the ability to program the device in package while greatly reducing or eliminating the risk of ESD induced reprogramming. Also, there is no need for an additional probe pad required by other solutions.

### BRIEF DESCRIPTION OF THE DRAWINGS

For a more complete understanding of the present invention, reference is made to the following detailed description taken in conjunction with the accompanying drawings wherein:

FIG. 1 is a schematic diagram of the circuit of the present invention; and

FIG. 2 shows SPICE simulation results illustrating the transient response of the circuit of FIG. 1.

### DETAILED DESCRIPTION OF THE INVENTION

The numerous innovative teachings of the present invention will be described with particular reference to an exemplary embodiment. However, it should be understood that the exemplary embodiment is only one example of the many advantageous embodiments and innovative teachings herein. In general, statements made in the specification of the application do not necessarily delimit any of the various claimed inventions. Moreover, some statements may apply to some inventive features, but not to others. Detailed descriptions of known functions and constructions unnecessarily obscuring the subject matter of the present invention have been omitted for clarity.

A small number of EEPROM cells, typically less than one hundred bits, is used on servo motor controller ICs, including CMOS monolithic integrated circuits, as a cost effective means of fine tuning the performance of the silicon and reducing the effect of manufacturing variations. The bits are programmed by applying a signal of fifteen (15) to twenty (20) volts on internal circuit nodes. The applied voltage can be selected to program or erase a particular bit. However, if a pin is used to pass the 15 to 20 volt signal internally to the EEPROM circuit, then ESD induced by ordinary handling of the device can inadvertently introduce a high voltage to the circuit and accidentally program, reprogram or erase a bit or several bits through that pin.

An alternative method of addressing the problem of data reprogramming or erasure requires that the IC's be tested and trimmed for optimum performance only at the wafer level using multi-probe test via an additional internal probe pad. Disadvantageously, ESD events that cause data reprogramming or erasure can occur in the process of dicing individual ICs from the wafer, mounting it on a lead frame and encapsulating it in a plastic package. Thus, an improved circuit and method is desired that permits programming of the EEPROM cells after device packaging. The present invention comprises a circuit and method for retaining the ability to program the device in package while greatly reducing or eliminating the risk of ESD induced reprogramming or erasure.

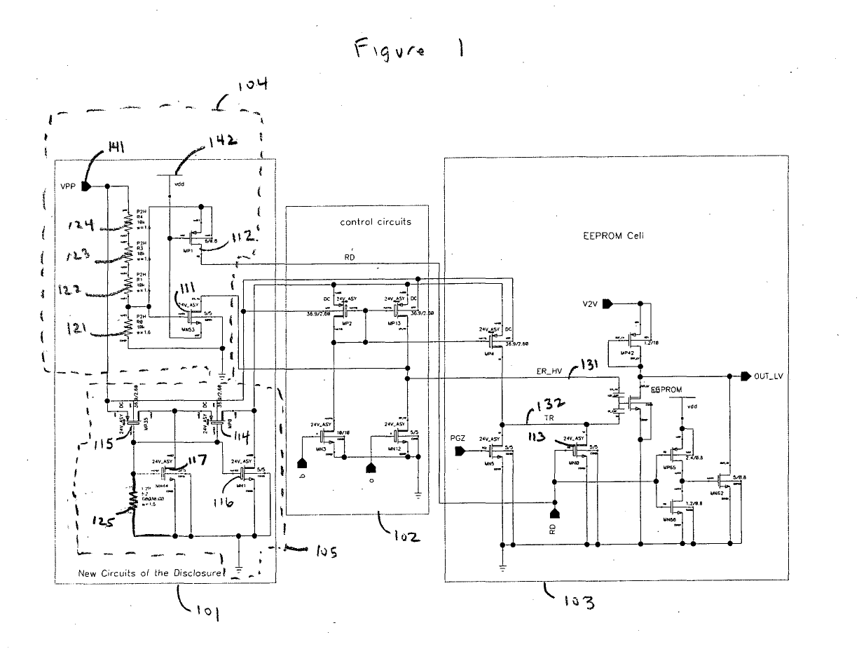

Three functional blocks are seen in FIG. 1, the circuit of the present invention being circuit 101, said circuit 101 shown being coupled to control circuit 102 and data cell 103, in this case, an EEPROM cell. As seen in FIG. 1, clamp circuit 104 of circuit 101 is comprised of a first transistor 111 and a second transistor 112, and a voltage divider comprised of a first, second, third and fourth resistor 121, 122, 123 and 124. As seen therein, transistor 111 comprises an NMOS transistor and transistor 112 comprises a PMOS transistor. A delay circuit 105 is comprised of a fourth, fifth, sixth and seventh transistor 114, 115, 116, 117 and a fifth resistor 125. As seen therein, transistors 114 and 115 comprise PMOS transistors and transistors 116 and 117 comprise NMOS transistors. More specifically, as seen therein, the delay circuit 105 dictates the operation during transient conditions of an ESD event, while the clamp circuit 104 controls the operation when steady state or DC condition is reached. Circuit 101 is operable to keep the signals at the EEPROM input nodes 131 and 132 below 10 volts.

In operation, if there is an ESD event or high voltage spike introduced on line Vpp 141, which is an input to the clamp circuit, voltage on line Vpp 141 can reach 25 volts in less than 10 nanoseconds. The voltage divider circuit of resistors 121, 122, 123 and 124 will put approximately between four (4) and six (6) volts of the ESD voltage on the gate of transistor 111 and the source and substrate terminals of transistor 112. Since line Vdd 142 has much more capacitance due to the parasitic capacitance of all circuits on the IC that are connected to Vdd, it will rise more slowly, so the voltage at Vdd 142 will be close to zero during a high voltage spike or ESD event. This in turn pulls the gate terminal of transistor 113 up and pulls the gate of transistor 111 down. In normal operation when Vdd 142 is at approximately five 5 volts, then transistors 111 and 112 are both off.

In order to allow circuit 101 time to react to a high voltage spike or ESD event, a mechanism is required to delay the propagation of the high voltage on Vpp 141. This is accomplished as follows: Gates of transistors 114 and 115 are tied to ground through a large resistance so the rapid voltage rise at Vpp 141 tends to couple through and pull up the gate node, which is shared by all of the transistors in delay circuit 105, and charges the high resistance path on Vpp 141 until resistor 125 can discharge it. About the time that the fifth resistor 125 discharges, clamp circuit 104 dominates to provide the dc operating condition required for pulling down EEPROM input nodes 131 and 132.

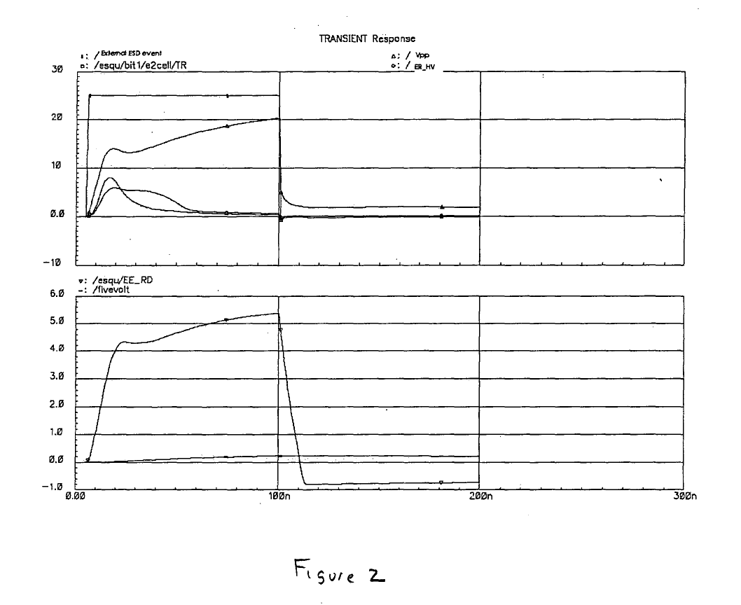

As seen in FIG. 2, a simulated external ESD pulse rises from 0 to 25V in a very short time. As a result, VPP line 141 rises up to about 15V in about 10 ns and continues rising to about 20V, which is high enough to reprogram or erase the EEPROM cells. But, the delay circuit 105 retards the fast rise of VPP until the clamp circuit 104 can pull down EEPROM input nodes 131 and 132 to low, safe voltage levels and prevent reprogramming of the cells.

The present invention may be described herein in terms of various functional components. It should be appreciated that such functional components may be realized by any number of hardware or structural components configured to perform the specified functions. For example, the present invention may employ various integrated components which are comprised of various electrical devices, such as resistors, transistors, capacitors, diodes and the like whose values may be suitably configured for various intended purposes. Additionally, the various components may be implemented in alternate ways, such as, for example, the changing of polarity types of transistor devices and the changing of the polarity of the circuits. These alternatives can be suitably selected depending upon the particular application or in consideration of any number of factors associated with the operation of the circuits and systems. Such general applications that may be appreciated by those skilled in the art in light of the present disclosure are not described in detail herein. Further, it should be noted that while various components may be suitably coupled or connected to other components within the exemplary circuit, such connections and couplings can be realized either by direct connection between components, or by connection through other components and devices located there between. These and other changes or modifications are intended to be included within the scope of the present invention, as expressed in the following claims.

1. A circuit for minimizing the effects of ESD events on data cells, comprising:
a clamp circuit with an input and output to clamp after an ESD event;
a delay circuit with an input and an output to delay during said ESD event; and
the coupled clamp circuit and delay circuit operable to keep voltage to one or a plurality of input nodes coupling the output of the delay circuit to a data cell below a predetermined threshold.

2. The circuit for minimizing the effects of ESD events on data cells of claim 1, further comprising:
the delay circuit being operable to dictate the operation during transient conditions of an ESD event;
the clamp circuit being operable to control the operation when a steady state or DC condition is reached.

3. The circuit for minimizing the effects of ESD events on data cells of claim 1, further comprising a data cell with one or a plurality of input nodes responsively coupled to the output of the delay circuit.

4. The circuit for minimizing the effects of ESD events on data cells of claim 3, wherein the data cell comprises an EEPROM cell.

5. The circuit for minimizing the effects of ESD events on data cells of claim 1, wherein the predetermined voltage threshold is approximately 10 volts.

6. The circuit for minimizing the effects of ESD events on data cells of claim 1, wherein the clamp circuit further comprises:
a voltage divider circuit;
a first transistor;
a second transistor;
a first node;
a second node;
the voltage divider operable to place a voltage on the gate of the first transistor and the source/bulk of the second transistor in the event of an ESD event on the first node;
the second node having a capacitance operable to cause it to rise more slowly during an ESD event;
the gate terminal of the third transistor and the gate of the first transistor being coupled to the second node, operable to cause the gate terminal of the third transistor to be pulled up and the gate of the first transistor to be pulled down as the voltage on the second node rises; and
the first transistor and second transistor being turned off during normal operation when the second node is at approximately five volts.

7. The circuit for minimizing the effects of ESD events on data cells of claim 6, wherein the voltage divider further comprises a plurality of resistors being coupled in series.

8. The circuit for minimizing the effects of ESD events on data cells of claim 6, wherein the voltage divider is operable to place a voltage between approximately four (4) and six (6) volts on the gate of the first transistor and the source/bulk of the second transistor in the event of a high voltage signal on the first node.

9. The circuit for minimizing the effects of ESD events on data cells of claim 6, wherein the transistors comprise MOSFETs.

10. The circuit for minimizing the effects of ESD events on data cells of claim 9, further comprising:
the first transistor being an NMOS type; and
the second transistor being a PMOS type.

11. The circuit for minimizing the effects of ESD events on data cells of claim 6, wherein the delay circuit further comprises:
a fourth transistor;
a fifth transistor;
a sixth transistor;
a seventh transistor;
a fifth resistor; and
the delay circuit being operable to delay the propagation of a high voltage signal introduced at the first node Vpp.

12. The circuit for minimizing the effects of ESD events on data cells of claim 11, wherein the delay circuit further comprises:
a ground reference;
the gate of the fourth transistor and the gate of the fifth transistor being coupled to the ground reference through a large resistance;
the delay circuit operable to cause any rapid voltage rise on the first node Vpp to couple through and pull up the gates of all the transistors, and charge the high resistance path Vpp until the fifth resistor discharges the voltage;
the clamp circuit dominating to provide the dc operating condition required for pulling down one or a plurality of data cell input nodes upon discharge of the fifth resistor; and
the sixth transistor and seventh transistor being operable to slow the voltage rise through the circuit output through an RC time delay.

13. The circuit for minimizing the effects of ESD events on data cells of claim 11, wherein the transistors comprises MOSFETs.

14. The circuit for minimizing the effects of ESD events on data cells of claim 13, wherein the fourth transistor comprises a PMOS, the fifth transistor comprises a PMOS, the sixth transistor comprises an NMOS and the seventh transistor comprises an NMOS.

15. The circuit for minimizing the effects of ESD events on data cells of claim 1, further comprising a CMOS circuit.

16. The circuit for minimizing the effects of ESD events on data cells of claim 1, for use in a servo motor controller.

17. The circuit for minimizing the effects of ESD events on data cells of claim 16, for use in a computer hard drive controller.

18. A circuit for shunting high voltage signals, comprising:
a clamp circuit with an input and output to clamp after an ESD event;
a delay circuit with an input and an output to delay during said ESD event;
the output of the clamp circuit responsively coupled to the input of the delay circuit; and
the coupled clamp circuit and delay circuit operable to shunt voltage above a certain threshold to ground.

19. The circuit for shunting high voltage signals of claim 18, further comprising a CMOS circuit.

20. The circuit for shunting high voltage signals of claim 18, for use in a servo motor controller.

21-26 (cancelled).
